(19) United States
(12) Patent Application Publication
(10) Pub. No.: US 2020/0264345 A1
(43) Pub. Date: Aug. 20, 2020

(54) Work Platform And Method For Rapidly And Precisely Measuring Concentration Dependent Diffusion Coefficients Of Binary Solutions Using An symmetric Liquid-Core Cylindrical Lens

(71) Applicant: Yunnan University, Kunming (CN)

(72) Inventors: Xiaoyun Pu, Kunming (CN); Li Wei, Kunming (CN); Weidong Meng, Kunming (CN)

(73) Assignee: Yunnan University, Kunming (CN)

(21) Appl. No.: 16/659,546

(22) Filed: Oct. 21, 2019

(30) Foreign Application Priority Data
Oct. 25, 2018 (CN) 201811250468.0

(51) Int. Cl. G02B 3/12; G01B 11/24; H01S 5/02; H04N 5/374

(52) U.S. Cl. CPC G02B 3/12; G01B 11/24; H04N 5/23222; H04N 5/374; H01S 5/02

(57) ABSTRACT

The present invention provides a platform and a method for rapidly and precisely measuring concentration-dependent diffusion coefficients of binary solution. The key element of the platform is an asymmetric liquid-core cylindrical lens, which acts as both diffusion cell and imaging device to take diffusion image, concentration spatial and temporal profile of diffusion solution, C^{e}(z, t), can be deduced from the diffusion image. Assuming concentration-dependent diffusion coefficient to be a polynomial D(C)=D₀(1+α₁C+α₂C²+α₃C³+ . . . ), where D₀, α₁, α₂ and α₃ are under-determined parameters, the finite difference method is applied to solve numerically Fick diffusion equation, the calculated concentration profiles (Cⁿ(z, t)s) by varying the under-determined parameters are compared with the C^{e}(z, t), the parameters corresponding minimum concentration standard deviation are selected to determine D(C). Ray tracing method is used to simulate diffusion image, the comparison between simulated and experimental images gives a direct proof for the correctness of the obtained D(C).

### CROSS-REFERENCES TO RELATED APPLICATIONS

This application claims priority from Chinese Application Serial Number 201811250468.0 filed Oct. 25, 2018, which is hereby incorporated herein by reference in its entirety.

### TECHNICAL FIELD

The invention relates to a measurement method of concentration-dependent diffusion coefficients of binary solutions in the field of liquid mass transfer process.

### BACKGROUND OF THE INVENTION

Diffusion coefficient (D) is the important datum for the study of liquid mass transfer process, and its accurate measurement has important scientific significance and application value for physics, chemical industry, biology, medicine, environmental protection and other scientific fields. D value is generally concentration-dependent (D(C)), unfortunately, there is not a general theory to date that gives satisfactory D(C) description even in binary liquid diffusion processes, therefore, experiments are usually necessary in order to determine precise D(C) of different diffusion system required in mass transfer calculation.

Diaphragm cell^{[1]} was utilized to measure concentration-dependent liquid diffusion coefficients in the aqueous solutions of HCl, authors retrieved information about the first and second derivative of the diffusion coefficient with respect to concentration, D(C) was given in the form of Taylor series. It is necessary for Diaphragm cell method to carry on a number of diffusion experiments with different concentrations. Holographic interferometry^{[2]} was applied to acquire concentration-dependent liquid diffusion coefficients in the aqueous solutions of KCl, D(C) was given in the form of polynomial. Holographic interferometry method also requires a number of experiments and extremely strict experimental environment. Raman spectroscopy was used to measure liquid diffusion coefficients of binary systems of benzene/n-hexane, benzene/cyclohexane, benzene/acetone^{[3]} and ethyl acetate/cyclohexane^{[4]}, concentration-dependent liquid diffusion coefficients were listed in tables and in the form of polynomial, respectively. Because Raman scattering is a weak effect, strong Stocks band associated with diffusion component must exist and an expensive Raman image spectrometer is necessary. Nuclear magnetic resonance was used to measure liquid diffusion coefficients of TEA/H₂O^{[5]} and cyclohexane/n-hexane/toluene^{[6]}, which required the target nucleus had non-vanishing nuclear magnetic moment, and expensive equipment. Besides the disadvantages mentioned above, those four methods are time-consuming processes and have a heavy workload.

To rapidly and precisely measure concentration-dependent diffusion coefficients of binary solutions from a single experiment and observe directly liquid diffusion processes, the present invention acquires diffusion image using an asymmetric liquid-core cylindrical lens (ALCL)^{[7-9]}, the concentration spatial and temporal profile of diffusion solution, C^{e}(z, t)s, can be deduced from the diffusion images. The algorithm of finite difference method (FDM)^{10]} is applied to solve numerically Fick diffusion equation, the calculated diffusion concentration profiles, Cⁿ(z, t)s, are compared with experimental concentration profiles to determine concentration-dependent diffusion coefficient D(C) in the invention.

One of positive result of the invention is that only a single diffusion image taken at suitable time (t₀) is required to rapidly measure concentration-dependent liquid D(C), therefore, the invention can greatly shorten the experimental time required to measure concentration-dependent liquid D(C).

Another positive result of the invention is that the invention provides a new method for measuring concentration-dependent liquid D(C) precisely. The method calculates average value of concentration-dependent liquid D(C) taken at different diffusion time, the D(C) average value is more precise than that one single measured value.

The third positive result of the invention is the verification of obtained D(C). Based on the D(C), the diffusion images at any other time (tᵢ≠t₀) can be simulated by means of ray tracing method, the simulated diffusion images are compared with that of experimental images to verify the correctness of calculated D(C).

### SUMMARY OF THE INVENTION

The invention, in one aspect, provides a work platform for acquiring diffusion images. The work platform, as shown in FIG. 1, comprises (1) a semiconductor low-power laser, which acts as light source of the working platform; (2) a light beam collimating and expanding device, which is located behind the laser and constituted by an object lens, a pinhole filter and a Large-aperture spherical lens; (3) a rectangular slit with adjustable width, which is located behind the beam collimating and expanding device; (4) an asymmetrical liquid cylindrical lens (ALCL), located behind the rectangular slit, which acts as both diffusion cell and key imaging element; (5) a CMOS camera disposed on a moveable track, which is located behind the ALCL.

The invention, in another aspect, provide an asymmetrical liquid cylindrical lens (ALCL) as shown in FIG. 2), which is comprised by sticking two different cylindrical lenses together. The performance of the ALCL is characterized by four parameters: (1) refractive index resolution (Δf), which is defined as the change of focal length of the ALCL caused by the change of liquid refractive index (Δn); (2) measurement deviation of focal length (δf), which is defined as the depth of field (DOF) of the ALCL; (3) minimum resolved refractive index (δn), which is defined as δn=Δn/(Δf/δf); (4) spherical aberration (SA), which is defined as the difference between two focal lengths (f₁−f₂), where f₁ is the focal length calculated by Gauss imaging formula, f₂ is the focal length based on Snell refractive law for the marginal light ray. The four characteristic parameters are adjusted to required values by selecting the sizes of the two cylindrical lenses that include four curvature radii R₁, R₂, R₃, R₄ of the lenses, and the distances between each spherical face d₁, d₂, d₃, d₄.

The invention, in till another aspect, provides a method for treating diffusion images in order to obtain experimental concentration profile C^{e}(zⱼ, t₀). The method comprises four steps of (1) binarizing the diffusion image; (2) extracting image width as a feature parameter, and changing the parameter into related refractive index of diffusion solution; (3) changing the refractive index into related concentration of diffusion solution, and obtaining the profile of C^{e}(zⱼ, t₀); (4) calculating the concentration profile C^{e}(zⱼ, t₀) in the range of low concentration area, and obtaining the diffusion coefficient Do in the condition of infinite dilute solution, which is the boundary condition for solving numerically Fick diffusion equation.

The invention, in a further aspect, provides a method for solving numerically Fick diffusion equation, which can be written as

$$\frac{\partial C ( z , t )}{\partial t} = \frac{\partial D ( C )}{\partial z} \frac{\partial C ( z , t )}{\partial z} + D ( C ) \frac{{\partial }^{2} C ( z , t )}{\partial {z}^{2}} ; \qquad ( S \text{-} 1 )$$

where D(C) is concentration dependent diffusion coefficient; C(z, t) is the concentration profile along the one-dimension diffusion direction z-axis at time t, D(C) can be expressed in the form of polynomial

D(C)=D₀(1+α₁C+α₂C²+α₃C³+ . . . ); (S-2)

where α₁, α₂, α₃, . . . are the under-determined coefficients. Assuming z=0 to be interface between two diffusion solutions, initial concentrations in two sides of the interface be C₁ and C₂, and each solution height filled in the ALCL be H, the boundary conditions of Equation (S-1) satisfy with

$$\{ \begin{matrix}C ( z > 0 , t = 0 ) = {C}_{1} \\ C ( z \leq 0 , t = 0 ) = {C}_{2}\end{matrix} , \{ \begin{matrix}C ( z = H , t > 0 ) = {C}_{1} \\ C ( z = - H , t > 0 ) = {C}_{2}\end{matrix} . \qquad ( S \text{-} 3 )$$

A group of initial parameters [(α₁)₁, (α₂)₁, (α₃)₁] in Equation (D-2) are set by experience to determine D(C); the finite difference method (FDM)^{[1]}, the implicit FDM^{[2]} and the chasing method^{[3]} in computational mathematics are used to solve numerically the Equation (S-1) under the initial and boundary conditions of Equation (S-3). The calculated concentration spatial and temporal profile at any diffusion time are written as Cⁿ(zⱼ, t₁), =0, 1, . . . M+1; i=0, 1, 2, . . . ).

The invention, in a further aspect, provides a method for determining under-determined coefficients (α₁, α₂, α₃, . . . ) in Equation (S-2). The method compares the calculated C(zⱼ, tᵢ) with the experimental C^{e}(zⱼ, t₀), (j=0, 1, 2, . . . , M+1), and calculates standard deviation σₖ defined in Equation (S-4)

$${σ}_{k} = \frac{\sqrt{{\sum }_{0}^{M + 1} {( {C}^{n} ( {z}_{j} , {t}_{0} ) - {C}^{e} ( {z}_{j} , {t}_{0} ) )}^{2}}}{\sqrt{M + 1}} , \\ ( j = 0 , 1 , … , M + 1 ; k = 1 , 2 , … , N . \qquad ( S \text{-} 4 )$$

A series σₖs(k=2, 3, . . . , N) is calculated by varying under-determined parameters [(α₁)ₖ, (α₂)ₖ, (α₃)ₖ], the parameters corresponding the minimum value of σₖs are the best-fit parameters, which are selected to determine D(C)=D₀[1+(α₁)_{best}×C+(α₂)_{best}×C²+(α₃)_{best}×C³+ . . . ].

The invention, in a further aspect, provides a method for verifying the correctness of calculated D(C). The method uses the FDM to solve numerically the Equation (S-1) to get the refractive index spatial and temporal profile nⁿ(zⱼ, tᵢ) based on the calculated D(C); ray tracing method is applied to simulate diffusion image at any diffusion time, the simulated diffusion images are compared with the experimental diffusion images to verify the correctness of calculated D(C).

One object of the invention is to provide a novel optical method for measuring concentration-dependent liquid D(C) rapidly. The method requires only a single diffusion image taken at suitable time, which greatly shortens the experimental time required to measure concentration-dependent liquid D(C).

Another object of the invention is to provide a new method for measuring concentration-dependent liquid D(C) precisely. The method calculates average value of concentration-dependent liquid D(C) taken at different diffusion time, the D(C) average value is more precise than that one single measured value.

A further object of the invention is to provide a method for verifying the correctness of calculated D(C). Based on the calculated D(C), the diffusion images at any other time can be simulated by means of ray tracing method, the comparison between the simulated and experimental images give a direct verification of the calculated D(C).

These and other aspects, feature and advantages of the invention will be understood with reference to the drawing figures and detailed description herein, and will be realized by means of the various elements and combinations. It is to be understood that both the foregoing general description and the following brief description of the drawing and detailed description of the invention are exemplary and explanatory of preferred embodiments of the invention, and are not restrictive of the invention, as claimed.

### BRIEF DESCRIPTION OF THE DRAWINGS

FIG. 1 is a schematic view of work platform for acquiring diffusion images. The work platform is composed by five parts, which are (1) A semiconductor low-power laser, (2) A light beam collimating and expanding device, (3) A rectangular slit with adjustable width, (4) An asymmetry liquid-core cylindrical lens (ALCL) and (5) A CMOS camera.

FIG. 2 is a schematic view of the ALCL labeled with parameters. The curvature radii of two cylindrical lenses are R₁=32.0 mm, R₂=24.0 mm, R₃=34.7 mm and R₄=79.5 mm. The distances between each spherical face are d₁=d₄=3.0 mm, d₂=1.8 mm, and d₃=1.2 mm. The width of liquid core is 2h₁=18.2 mm, and the width of cylindrical lens is 2h₂=26.2 mm.

FIG. 3 is the curves of characteristic parameter of the ALCL, where solid curve is the sensitivity of refractive index(Δf), dash curve is measurement deviation of focal length (δf=DOF), and point curve is the minimum resolvable refractive index (δn).

FIG. 4 is the spherical aberration (SA) of the ALCL varied with liquid refractive index.

FIG. 5 is the diffusion image appearing on the CMOS plane when collimated monochromatic light passing through the ALCL. A gradient distribution of refractive index is formed in the diffusion cell along the diffusion direction (z-axis), n₁<n₂<n₃=n_{c}<n₄.

FIG. 6 is the experimental diffusion images taken at different diffusion time. (a) 120 min, (b) 180 min, (c) 240 min; (d) 270 min; (e) 300 min; (f) 360 min. The vertical scale is concentration in unit of mass fraction, and the point line indicates that liquid layer of refractive index (RI=n)=n_{c} moves with diffusion time. CMOS detector is fixed at the position where collimated beams can be sharply imaged after passing through the solution of RI=n=n_{c}=1.3619.

FIG. 7 is the relationship between the width of diffusion image and the RI=n of solution filled in the liquid core. When collimated monochromatic light passes through the liquid of RI=n=n_{c}, the light will be focused on the CMOS plane; when the light passes through the liquid of RI=n<n_{c} and >n_{c}, it will project on the CMOS plane and generate a dispersion width of W.

FIG. 8 is the original diffusion image for the ethylene glycol aqueous solution at room temperature (298 K) taken at t=t₀=260 min, n_{c}=1.3619.

FIG. 9 is the binarized diffusion image of the FIG. 8).

FIG. 10a is the image-width profile W^{e}(z, t) deduced from the FIG. 9).

FIG. 10b is the curve of width of diffusion image varied with liquid RI=n. The solid circles are the measured values, while the lines are the calculated values.

FIG. 10c is the refractive index profile n^{e}(z, t) deduced from the FIG. 10).

FIG. 10d is the concentration profile C^{e}(z, t) deduced from the FIG. 12).

FIG. 11 is the comparison between the measured results by this invention and the literature values. The squares and dash line represent the D(C) curve measured by this invention; the dots represent the values measured by Ferna′ndez-Sempere (1996)^{[13]}; the triangles represent the values measured by Bogachev (1982)^{[14]}. Error bars, which are magnified 10 times for the sake of clarity, are determined by ten-time independent measurements.

FIG. 12 is the simulated calculation flow-chart of optical tracing method.

FIG. 13 is the comparison between measured diffusion image and simulated image for the ethylene glycol aqueous solution at room temperature (298 K), CMOS detector is fixed at the position where collimated beams can be sharply imaged after passing through the solution of RI=n=n_{c}=1.3387. (a): measured diffusion image, (a′): related simulation image. Images taken at t=t₀=240 min, 270 min, 300 min and 330 min, for (a), (b), (c) and (d), respectively.

FIG. 14 is the same as FIG. 16), except that the CMOS detector is fixed at the position where collimated beams can be sharply imaged after passing through the solution of RI=n=n_{c}=1.3619.

### DETAILED DESCRIPTION OF EXAMPLE EMBODIMENTS

The present invention may be understood more readily by reference to the following detailed description of the invention taken in connection with the accompanying drawing figures, which form a part of this description. It is to be understood that this inventions is not limited to the specific devices, methods, conditions or parameters described and/or shown herein, and that the terminology used herein is for the purpose of describing particular embodiments by way of example only and is not intended to be limiting of the claimed invention, Any and all patents and other publications identified in this specification are incorporated by reference as though fully set forth herein.

Measuring Concentration-Dependent Diffusion Coefficients of Ethylene Glycol Aqueous Solution at Room Temperature (298 K) Using an ALCL

The invention provides a work platform and a method for rapidly and precisely measuring concentration-dependent diffusion coefficients of binary solution. The work platform is used to acquire diffusion image, the method comprises: (1) acquiring experimental concentration profile C^{e}(zⱼ, t₀) from the diffusion images; (2) calculating concentration profile Cⁿ(zⱼ, t₀) based on diffusion equation; (3) obtaining the concentration-dependent diffusion coefficient D(C) by comparing C^{e}(zⱼ, t₀) with Cⁿ(zⱼ, t₀)s and (4) simulating diffusion images to verify the correctness of obtained D(C).

First of all, building up a work platform to acquire diffusion image.

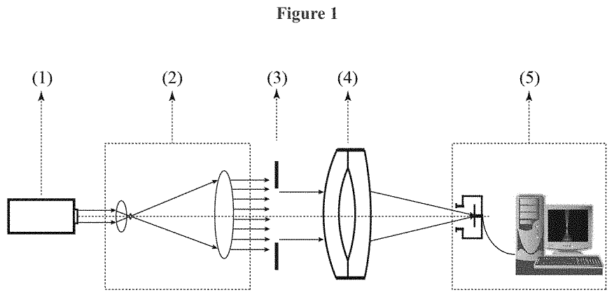

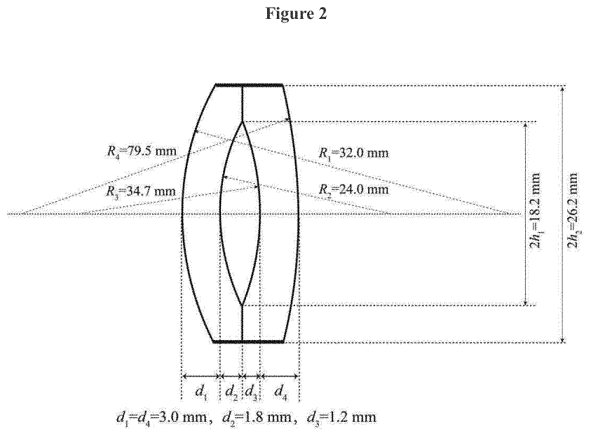

The work platform for acquiring diffusion images is shown in FIG. 1), which comprises five parts as follows: (1) a semiconductor low power laser (λ=589 nm, CW, maximum power 20 mw), which acts as light source of the working platform; (2) a light beam collimating and expanding device, which is located behind the laser and constituted by an object lens (×40), a pinhole filter (15 μm) and a large-aperture spherical lens (f=300 mm); (3) a rectangular slit with adjustable width (0˜13 mm), which is located behind the beam collimating and expanding device; (4) an asymmetrical liquid cylindrical lens (ALCL), located behind the rectangular slit, which acts as both diffusion cell and key imaging element; (5) a CMOS camera disposed on a moveable track, which is located behind the ALCL, the pixel size and resolution are 6.45 μm×6.45 μm and 3120 pixel×1392 pixel, respectively.

Furthermore, key device of the work platform is the ALCL, which acts as both diffusion pool and imaging optical element, the sizes of the ALCL are shown in FIG. (2). The length of the ALCL is L=50.0 mm, the material of the ALCL is BK9 glass of which refractive index is RI=n=n₀=1.5163.

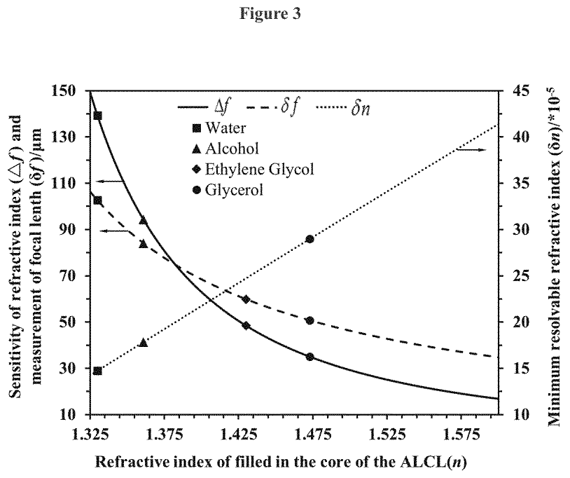

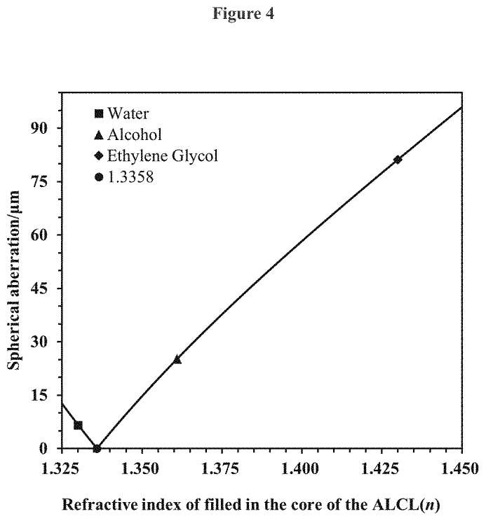

Furthermore, the characteristic parameters Δf (refractive index resolution), δf (measurement deviation of focal length) and δn (minimum resolved refractive index) are shown in FIG. 3) as the solid, dash and point curves, respectively. The characteristic parameter SA (spherical aberration) is shown in FIG. 4).

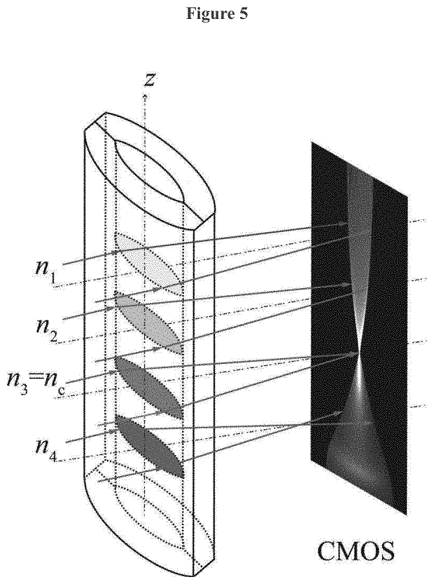

Furthermore, when collimated monochromatic light passing through the ALCL, the diffusion image appearing on the focal plane of the ALCL is a “beam waist” shaped image as shown in FIG. 5), the concentration spatial profile of diffusion solution can be deduced from the diffusion image. The diffusion image is varied with time, which reflects the dynamic diffusion process directly.

Furthermore, the diffusion images are closely related to the diffusion time as shown in FIG. 6). The images taken before t=180 min are deformed in the interface area, while the images taken after t=300 min do not satisfy with the boundary condition for FDM calculation. Therefore, the images selected to calculate the concentration-dependent diffusion coefficient D(C) are taken during the diffusion time of 300 min>t>180 min.

Secondly, acquiring experimental concentration profile based on a diffusion image at room temperature (298 K).

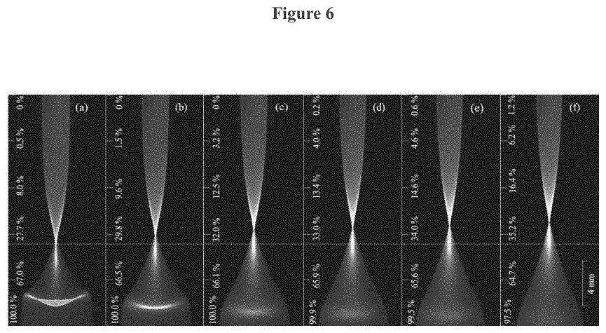

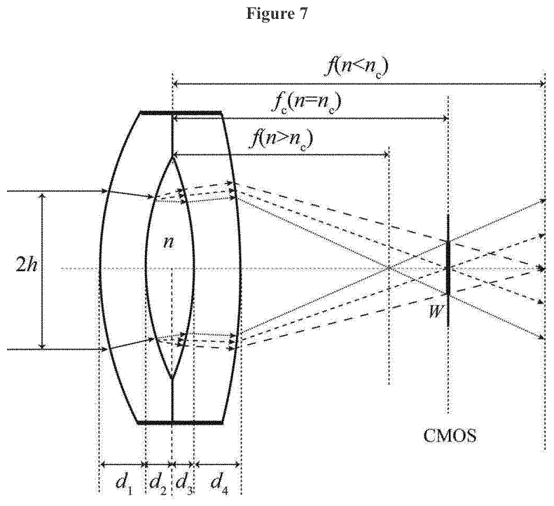

The relationship between image-width (W) and refractive index (RI=n) of the solution filled in the core of the used ALCL is shown in FIG. 7). When collimated monochromatic light passes through the liquid of RI=n=n_{c}, the light will be focused on the CMOS plane; when the light passes through the liquid of RI=n<n_{c} and >n_{c}, it will project on the CMOS plane and generate a dispersion width of W. One of diffusion image of ethylene glycol (EG) aqueous solution taken at t=t₀=260 min is shown in FIG. 8), CMOS detector is fixed at the position where collimated beams can be sharply imaged after passing through the solution of RI=n=n_{c}=1.3619.

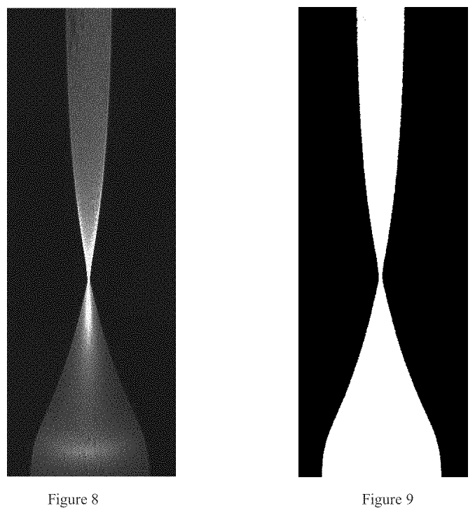

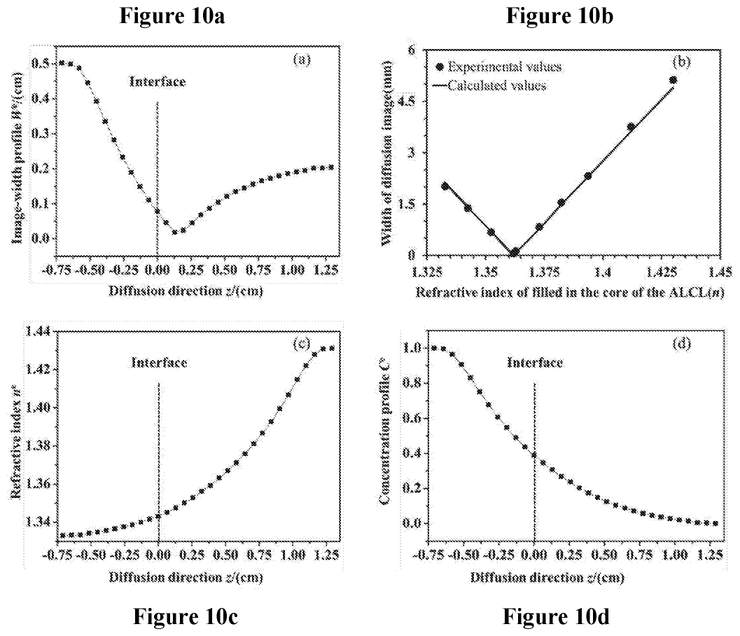

An experimental concentration profile is obtained from a diffusion image following the four steps: (1) binarizing the diffusion image of FIG. 8), the processed image is shown in FIG. 9); (2) extracting image widths from FIG. 9), the image-width profile W^{e}(z, t) is shown in FIG. 10a); (3) measuring the function relationship between image-width (W) and refractive index (RI) of EG aqueous solution (RI=n) filled in the core of the used ALCL, which can be determined either by solving imaging equations or measuring image-width and related refractive index of filled liquid with a Abbe refractometer[7], the measurement results are shown in FIG. 10b); the data in FIG. (10b) are fitted by a piecewise function as

$$n = \{ \begin{matrix}- 0.0148 W + 1.3627 , n < {n}_{c} , \\ 0.0134 W + 1.3614 , n > {n}_{c}\end{matrix} ; \qquad ( E \text{-} 1 )$$

the image-width profile W^{e}(z, t) is then changed into the RI=n profile n^{e}(z, t) based on Equation (E-1), which is shown in FIG. 10c); (4) measuring the relationship between the concentration of EG aqueous solution (C) and its RI=n, which is a linear function as follow

C(n)=10.16×n−13.542, (E-2)

the RI=n profile n^{e}(x, t) is then changed into the concentration profile C^{e}(zⱼ, t₀) based on Equation (E-2), which is shown in FIG. (10d).

Thirdly, measuring diffusion coefficient in infinite dilute condition (D₀).

Diffusion coefficient in infinite dilute condition (D₀) is the boundary condition for solving numerically Fick diffusion Equation (E-3),

$$\frac{\partial C ( z , t )}{\partial t} = \frac{\partial D ( C )}{\partial z} \frac{\partial C ( z , t )}{\partial z} + D ( C ) \frac{{\partial }^{2} C ( z , t )}{\partial {z}^{2}} \qquad ( E \text{-} 3 )$$

where C(z, t) represents the concentration profile along the one-dimension diffusion direction z-axis at time t, D(C) is the concentration-dependent coefficient that can be expressed in the form of polynomial as Equation (E-4),

D(C)=D₀(1++α₂C²+α₃C³+ . . . ); (E-4)

where α₁, α₂, α₃, . . . are the under-determined coefficients. Assuming z=0 to be interface between two diffusion solutions, initial concentrations in two sides of the interface be C₁ and C₂, and each solution height filled in the ALCL be H, boundary conditions satisfy with Equation (E-5),

$$\{ \begin{matrix}C ( z > 0 , t = 0 ) = {C}_{1} \\ C ( z \leq 0 , t = 0 ) = {C}_{2}\end{matrix} , \{ \begin{matrix}C ( z = H , t > 0 ) = {C}_{1} \\ C ( z = - H , t > 0 ) = {C}_{2}\end{matrix} . \qquad ( E \text{-} 5 )$$

The method introduced in reference^{[10]} has been used to obtain D₀ value, which fits the experimental concentration profile C^{e}(zⱼ, t₀) in the range of low concentration area with an analytical diffusion formula, and obtains the diffusion coefficient D₀ in the condition of infinite dilute solution. For the EG aqueous solution at room temperature (298 K), measured results are listed in the third row of Table 1, the average value is D₀=1.100×10⁻⁵ cm²/s.

Fourthly, solving Fick diffusion equation numerically using the algorithm of finite difference method.

The finite difference method (FDM)^{[10]}, the implicit FDM^{[11]} and the chasing method^{[12]} in computational mathematics are used to solve numerically the Equation (E-3) under the initial and boundary conditions of Equation (E-5). Assuming space step length along diffusion direction to be Δz=h, time step length to be Δt=τ, respectively, space and time coordinates become Equation (E-6),

z=zⱼ=jΔ=jh, j=0, 1, 2, . . . M+1,

t=tᵢ=iΔt=iτ, i=0, 1, 2, . . . . (E-6)

The spatial distance is divided into discrete M+2 terms, j=0 and M+1 are boundary terms. Equation (E-3) is changed to the difference quotient form in Equation (E-7),

$$\frac{{C}_{j}^{i + 1} - {C}_{j}^{i}}{τ} = \frac{( {D}_{j + 1}^{i} - {D}_{j - 1}^{i} )}{2 h} \times \frac{( {C}_{j + 1}^{i + 1} - {C}_{j - 1}^{i + 1} )}{2 h} + {D}_{j}^{i} \times \frac{( {C}_{j - 1}^{i + 1} - 2 {C}_{j}^{i + 1} + {C}_{j + 1}^{i + 1} )}{{h}^{2}} . \qquad ( E \text{-} 7 )$$

Let rⱼ₋₁ⁱ=τ×Dⱼ₋₁ⁱ/h², rⱼⁱ=τ×Dⱼⁱ/h² and rⱼ₊₁ⁱ=τ×Dⱼ₊₁ⁱ/h² for the convenience of calculation, Equation (E-7) is simplified as Equation (E-8),

$${C}_{j}^{i + 1} - {C}_{j}^{i} = \frac{{r}_{j + 1}^{i} - {r}_{j - 1}^{i}}{4} \times ( {C}_{j + 1}^{i + 1} - {C}_{j - 1}^{i + 1} ) + {r}_{j}^{i} \times ( {C}_{j - 1}^{i + 1} - 2 {C}_{j}^{i + 1} + {C}_{j + 1}^{i + 1} ) . \qquad ( E \text{-} 8 )$$

Let Aⱼⁱ)/(rⱼ₊₁ⁱ−rⱼ₋₁ⁱ)/4 and Bⱼⁱ=rⱼⁱ; =Equation (E-8) is further simplified as Equation (E-9),

(Aⱼⁱ−Bⱼⁱ)Cⱼ₋₁ⁱ⁺¹+(1+2Bⱼⁱ)Cⱼⁱ⁺¹+(Aⱼⁱ−Bⱼⁱ)Cⱼ₊₁ⁱ⁺¹Cⱼⁱ. (E-9)

Equation (E-9) is expanded into a series linear equations from j=1 to M

$$\begin{matrix}\{ \begin{matrix}( {A}_{1}^{i} - {B}_{1}^{i} ) {C}_{0}^{i + 1} + ( 1 + 2 {B}_{1}^{i} ) {C}_{1}^{i + 1} - ( {A}_{1}^{i} + {B}_{1}^{i} ) {C}_{2}^{i + 1} = {C}_{1}^{i} \\ ( {A}_{2}^{i} - {B}_{2}^{i} ) {C}_{1}^{i + 1} + ( 1 + 2 {B}_{2}^{i} ) {C}_{2}^{i + 1} - ( {A}_{2}^{i} + {B}_{2}^{i} ) {C}_{3}^{i + 1} = {C}_{2}^{i} \\ … \\ ( {A}_{M}^{i} - {B}_{M}^{i} ) {C}_{M - 1}^{i + 1} + ( 1 + 2 {B}_{M}^{i} ) {C}_{M}^{i + 1} - ( {A}_{M}^{i} + {B}_{M}^{i} ) {C}_{M + 1}^{i + 1} = {C}_{M}^{i}\end{matrix} . & ( E \text{-} 10 )\end{matrix}$$

If Cⱼⁱ⁼⁰ s(j=0, 1, . . . M+1) are given by initial condition, C(z, t) at any diffusion time can be calculated numerically by solving Equation (E-10). In order to do it, Equation (E-10) is changed into the form of tridiagonal matrix Equation (E-11),

$$[ \begin{matrix}{b}_{1}^{i} & {c}_{1}^{i} & 0 & … & … & … & 0 \\ {a}_{2}^{i} & {b}_{2}^{i} & {c}_{2}^{i} & 0 & … & … & 0 \\ 0 & {a}_{3}^{i} & {b}_{3}^{i} & {c}_{3}^{i} & 0 & … & 0 \\ 0 & … & … & … & … & … & 0 \\ 0 & … & … & … & … & … & 0 \\ 0 & … & … & 0 & {a}_{M - 1}^{i} & {b}_{M - 1}^{i} & {c}_{M - 1}^{i} \\ 0 & … & … & … & 0 & {a}_{M}^{i} & {b}_{M}^{i}\end{matrix} ] ( \begin{matrix}{C}_{1}^{i + 1} \\ {C}_{2}^{i + 1} \\ … \\ {C}_{M - 1}^{i + 1} \\ {C}_{M}^{i + 1}\end{matrix} ) = ( \begin{matrix}{C}_{1}^{i} - {a}_{1}^{i} {C}_{0}^{i + 1} \\ {C}_{2}^{i} \\ … \\ {C}_{M - 2}^{i} \\ {C}_{M}^{i} + {c}_{M}^{i} {C}_{M + 1}^{i + 1}\end{matrix} ) = [ \begin{matrix}{d}_{1}^{i} \\ {d}_{2}^{i} \\ {d}_{3}^{i} \\ ⋮ \\ {d}_{M - 1}^{i} \\ {d}_{M}^{i}\end{matrix} ] . \qquad ( E \text{-} 11 )$$

Where aⱼⁱ, bⱼⁱ and cⱼⁱ represent the coefficient terms before the Cⱼ₋₁ⁱ⁺¹, Cⱼⁱ⁺¹ and Cⱼ₊₁ⁱ⁺¹ in the expanded linear equations, which can be expressed as

$$\begin{matrix}{a}_{j}^{i} = {A}_{j}^{i} - {B}_{j}^{i} = \frac{{r}_{j + 1}^{i} - {r}_{j - 1}^{i}}{4} - {r}_{j}^{i} , j = 2 , 3 , … , M , & ( E \text{-} 12 a ) \\ {b}_{j}^{i} = 1 + 2 {B}_{j}^{i} = 1 + 2 {r}_{j}^{i} , j = 1 , 2 , 3 , … , M , & ( E \text{-} 12 b ) \\ {c}_{j}^{i} = {A}_{j}^{i} + {B}_{j}^{i} = \frac{{r}_{j + 1}^{i} - {r}_{j - 1}^{i}}{4} + - {r}_{j}^{i} , j = 1 , 2 , 3 , … M - 1. & ( E \text{-} 12 c )\end{matrix}$$

The initial and boundary conditions of Equation (E-5) are rewritten in discrete form as

$$\{ \begin{matrix}i = 0 ( t = 0 ) \\ j > M / 2 + 1 , {C}_{j}^{i = 0} = {C}_{1} \\ j \leq M / 2 + 1 , {C}_{j}^{i = 0} = {C}_{2}\end{matrix} , \{ \begin{matrix}∞ > i > 0 ( t > 0 ) \\ j = M + 1 , {C}_{M + 1}^{i} = {C}_{1} , {D}_{M + 1}^{i} = {D}_{0} \\ j = 0 , {C}_{0}^{i} = {C}_{2} \\ j < M + 1 , {D}_{j}^{i} = {D}_{0} \times [ 1 + {α}_{1} {C}_{j}^{i} + {{α}_{2} ( {C}_{j}^{i} )}^{2} + {{α}_{3} ( {C}_{j}^{i} )}^{3} + … ]\end{matrix} . \qquad ( E \text{-} 13 )$$

Using the chasing method^{[11]} in computational mathematics, and assuming a group of initial under-determined parameters [(α₁)₁, (α₂)₁, (α₃)₁] by experience to determine D(C), the concentration spatial and temporal profile Cⁿ(zⱼ, tᵢ) can be obtained by calculating Equation (E-11) under the boundary conditions of Equation (E-13).

Fifthly, comparing Cⁿ(zⱼ, t₀)s with C^{e}(zⱼ, t₀) to determine concentration-dependent diffusion coefficient D(C).

The calculated Cⁿ(zⱼ, tᵢ) at a special moment tᵢ=t₀ min is used to compare with the experimental profile C^{e}(zⱼ, t₀), (j=0, 1, 2, . . . , M+1), and standard deviation σₖ defined in Equation (E-14) is calculated.

$${σ}_{k} = \frac{\sqrt{{\sum }_{0}^{M + 1} {( {C}^{n} ( {z}_{j} , {t}_{0} ) - {C}^{e} ( {z}_{j} , {t}_{0} ) )}^{2}}}{\sqrt{M + 1}} , \\ ( j = 0 , 1 , … , M + 1 ; k = 1 , 2 , … , N ) . \qquad ( E \text{-} 14 )$$

Using the same method, a series σₖs (k=2, 3, . . . , N) is then calculated by varying under-determined parameters [(α₁)ₖ, (α₂)ₖ, (α₃)ₖ], the parameters corresponding the minimum value of aks are the best-fit parameters, which are selected to determine D(C) in the form of polynomial, that is, D(C)=D₀[1 (α₁)_{best}×C (α₂)_{best}×C²+(α₃)_{best}×C³+ . . . ].

For the EG aqueous solution at room temperature (298 K), measuring and fitting results of D(C) over a diffusion period from 240 to 285 min are listed in Table 1, where D₀=1.100×10⁻⁵ cm²/s, (α₁)_{best}=−0.8558, (α₂)_{best}=0.0016 and (α₃)_{best}=0.000003, leading to an average value of D(C)=1.100×10⁻⁵(1−0.8558C+0.0016C²+0.000003C³) cm²/s

TABLE 1
Measurement and fitting results of D(C) over a
diffusion period from 240 to 285 min

| C/ | D(C)/cm² · s⁻¹/×10⁻⁵ | | | | | | | | | | | | |
|---|---|---|---|---|---|---|---|---|---|---|---|---|---|
| | | | | | | | | | | | | σ/ | RSD/ |
| MF | 240 | 245 | 250 | 255 | 260 | 265 | 270 | 275 | 280 | 285 min | D̅ | ×10⁻⁵ | % |
| 0.0 | 1.102 | 1.111 | 1.085 | 1.123 | 1.138 | 1.111 | 1.075 | 1.086 | 1.082 | 1.089 | 1.100 | 0.019 | 0.017 |
| 0.1 | 1.005 | 1.005 | 1.006 | 1.005 | 1.006 | 1.006 | 1.006 | 1.007 | 1.007 | 1.007 | 1.006 | 0.001 | 0.099 |
| 0.2 | 0.910 | 0.911 | 0.911 | 0.911 | 0.912 | 0.912 | 0.913 | 0.913 | 0.913 | 0.913 | 0.912 | 0.001 | 0.110 |
| 0.3 | 0.815 | 0.816 | 0.817 | 0.816 | 0.817 | 0.818 | 0.819 | 0.820 | 0.820 | 0.820 | 0.818 | 0.002 | 0.244 |
| 0.4 | 0.720 | 0.721 | 0.722 | 0.722 | 0.723 | 0.724 | 0.725 | 0.726 | 0.726 | 0.726 | 0.724 | 0.002 | 0.276 |
| 0.5 | 0.625 | 0.627 | 0.628 | 0.627 | 0.629 | 0.630 | 0.632 | 0.633 | 0.633 | 0.633 | 0.630 | 0.003 | 0.476 |
| 0.6 | 0.530 | 0.532 | 0.533 | 0.533 | 0.535 | 0.536 | 0.538 | 0.540 | 0.540 | 0.540 | 0.536 | 0.004 | 0.746 |
| 0.7 | 0.435 | 0.437 | 0.439 | 0.438 | 0.441 | 0.443 | 0.445 | 0.447 | 0.447 | 0.447 | 0.442 | 0.004 | 0.905 |
| 0.8 | 0.340 | 0.342 | 0.345 | 0.344 | 0.347 | 0.349 | 0.352 | 0.354 | 0.354 | 0.354 | 0.348 | 0.005 | 1.437 |
| 0.9 | 0.245 | 0.248 | 0.250 | 0.249 | 0.253 | 0.255 | 0.258 | 0.261 | 0.261 | 0.261 | 0.254 | 0.006 | 2.362 |
| 1.0 | 0.150 | 0.153 | 0.156 | 0.155 | 0.159 | 0.161 | 0.165 | 0.168 | 0.168 | 0.168 | 0.160 | 0.006 | 3.750 |
| α₁ | −0.8640 | −0.8610 | −0.8590 | −0.8600 | −0.8570 | −0.8550 | −0.8520 | −0.8500 | −0.8500 | −0.8500 | −0.8558 | | |
| α₂ | 0.0004 | 0.0002 | 0.0009 | 0.0010 | 0.0013 | 0.0017 | 0.0020 | 0.0025 | 0.0027 | 0.0028 | 0.0016 | | |
| α₃ | 0.00000 | −0.00003 | 0.00000 | 0.00000 | 0.00002 | 0.00001 | −0.00003 | 0.00002 | 0.00001 | 0.00003 | 0.000003 | | |

α̅₁̅ = −0.8558, σ₁ = 0.0049; α̅₂̅ = 0.0016, σ₂ = 0.0009, α̅₃̅ = 0.0000, σ₃ = 0.00002; D̅(C) = 1.100 × 10⁻⁵(1 − 0.8558 C + 0.0016 C² + 0.000003 C³) cm²/s.

Sixthly, verifying the calculated D(C) by comparing it with literature values.

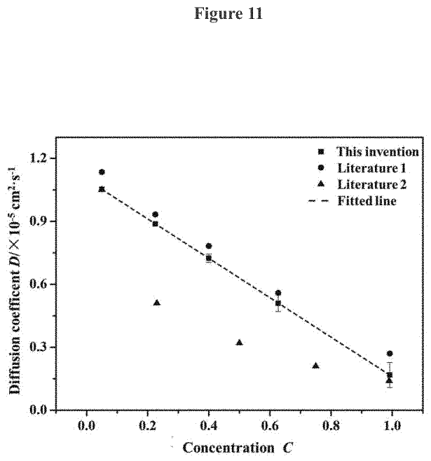

The obtained concentration-dependent diffusion coefficient D(C) by the present invention has been compared with the reported values of J. Ferna′ndez-Sempere (1996)^{[13]} and Bogachev (1982)^{[14]} for the same diffusion solution and at the same temperature (298K), the comparison results are shown in FIG. 11), which indicates that the values in our work distribute between the two literatures, and close to that measured by J. Ferna′ndez-Sempere with holographic interferometry.

Seventhly, verifying the calculated D(C) by simulating diffusion image at any diffusion time.

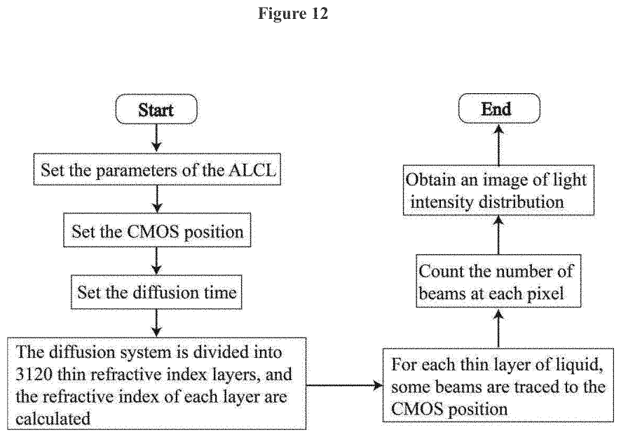

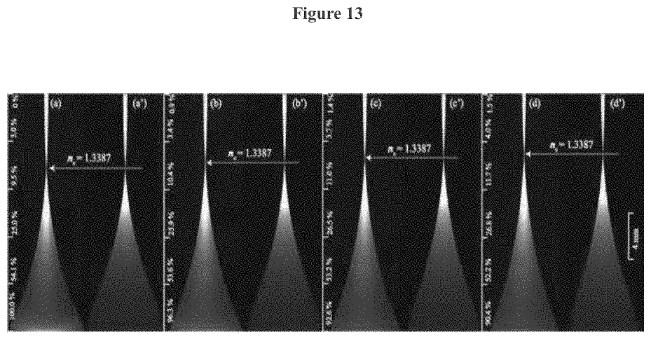

Based on the calculated D(C) and Equations (E-10) to (E-13), the FDM is used to solve numerically the diffusion Equation (E-3) to get the concentration spatial and temporal profile Cⁿ(zⱼ, tᵢ)s(j=0, 1, . . . M+1; i=0, 1, 2, . . . ), which are changed into the RI profile nⁿ(z, t) based on Equation (E-2). In order to verify the correctness of calculated D(C), ray tracing method is applied to simulate diffusion image at any diffusion time, the simulation calculation flow-chart of the ray tracing method is shown in FIG. 12).

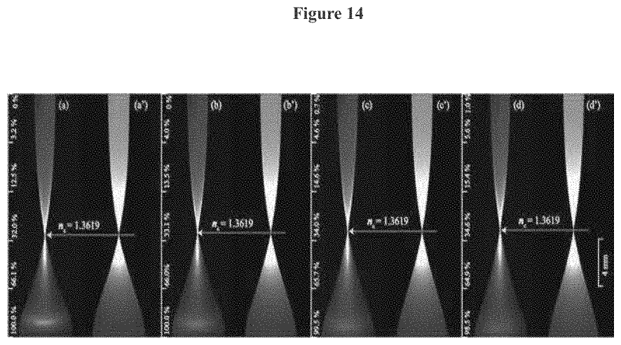

The simulated diffusion images are compared with the experimental diffusion images when CMOS is fixed on different positions, which are shown in FIG. 13) for RI=n=n_{c}=1.3387, in FIG. 14) for RI=n=n_{c}=1.3619. It is clear from the comparison that the simulated images match the measured diffusion images very well, either for the position where the solution layer (RI=n=n_{c}) is sharply imaged or for the whole image contour, demonstrating that the invented method is reliable in rapidly measuring concentration-dependent liquid diffusion coefficients of binary solution with high accuracy and stability.

While the invention has been described with reference to preferred and example embodiments, it will be understood by those skilled in the art that a variety of modifications, additions and deletions are within the scope of the invention, as defined by the following claims.

### REFERENCES

[1] J. C. Clunie, N. Li, M. T. Emerson, and J. K. Baird, “Theory and measurement of the concentration dependence of the differential diffusion coefficient using a diaphragm cell with compartments of unequal volume,” J. Phys. Chem. 94(15), 6099-6105(1990).
[2] C. Durou, C. Moutou and J. Mahenc, “Détermination des coefficients de diffusion différentiels isothermes par interférométrie holographique et simulation numerique,” J. Chim. Phys. 71(2), 271 (1974).
[3] R. W. Berg, S. B. Hansen, A. A. Shapiro and E. H. Stenby, “Diffusion measurements in binary liquid mixtures by Raman spectroscopy,” Appl. Spectrosc. 61(4), 367-373(2007).
[4] A. Bardow, V. Göke, H. J. Koß, K. Lucas and W. Marquardt, “Concentration-dependent diffusion coefficients from a single experiment using model-based Raman spectroscopy,” Fluid Phase Equilib. 228, 357-366(2005).
[5] C. F. Pantoja, Y. M. Muñoz-Muñoz, L. Guastar, J. Vrabec and J. Wist, “Composition dependent transport diffusion in non-ideal mixtures from spatially resolved nuclear magnetic resonance spectroscopy,” Phys. Chem. Chem. Phys. 20(44), 28185-28192(2018).
[6] A. Bardow, E. Kriesten, M. A. Voda, F. Casanova, B. Blümich and W. Marquardt, “Prediction of multicomponent mutual diffusion in liquids: Model discrimination using NMR data,” Fluid Phase Equilib. 278(1-2), 27-35(2009).
[7] L. C. Sun, W. D. Meng, X. Y. Pu “New method to measure liquid diffusivity by analyzing an instantaneous diffusion image,” Opt. Express 23(18), 23155-23166(2015).
[8] L. C. Sun, C. Du, Q. Li and X. Y. Pu, “Asymmetric liquid-core cylindrical lens used to measure liquid diffusion coefficient,” Appl. Opt. 55(8), 2011-2017(2016).
[9] L. C. Sun and X. Y. Pu, “A novel visualization technique for measuring liquid diffusion coefficient based on asymmetric liquid-core cylindrical lens,” Sci. Rep. 6(28264), 1-8 (2016).
[10] A. Taflove, S. C. Hagness, Computational electrodynamics: the finite-difference time-domain method (Artech house, 2005).
[11] D. A. Murio, “Implicit finite difference approximation for time fractional diffusion equations,” Comput. Math. Appl. 56(4): 1138-1145(2008).
[12] G. H. Golub and J. H. Welsch, “Calculation of Gauss quadrature rules,” Math. Comput. 23(106), 221-230(1969).
[13] J. Fernández-Sempere, F. Ruiz-Beviá, J. Colom-Valiente and F. Más-Pérez, “Determination of diffusion coefficients of glycols,” J. Chem. Eng. Data 41(1), 47-48 (1996).
[14] I. S. Bogacheva, K. B. Zemdikhanov and A. G. Usmanov, “Molecular diffusion coefficients and other properties of binary solutions of some liquid organic compounds,” Izv. Vyssh. Uchebn. Zaved., Khim. Khim.Tekhnol. 25 (2), 182-186(1982)

What is claimed is:

1. A work platform for acquiring diffusion images, comprising:
a semiconductor low-power laser, wherein the laser acts as light source of the working platform;
a light beam collimating and expanding device, wherein the device is located behind the laser and comprises at least an object lens,
a pinhole filter and a large-aperture spherical lens;
a rectangular slit with adjustable width, wherein the slit is located behind the beam collimating and expanding device;
an asymmetric liquid-core cylindrical lens (ALCL), wherein the lens is located behind the rectangular slit, and acts as both diffusion cell and key imaging element;
a CMOS camera disposed on a moveable track, wherein the camera is located behind the ALCL, and takes diffusion images formed on the CMOS plane.

2. The work platform of claim 1, wherein the ALCL is formed by a combination of two different cylindrical lenses together;
wherein the ALCL has an ideal refractive index resolution for measuring a diffusion solution and a small spherical aberration in the range of measurement concentration;
wherein the ALCL comprises four curvature radii R₁, R₂, R₃, R₄ of the cylindrical lenses, and the distances between each spherical face are d₁, d₂, d₃, d₄;
wherein R₁, R₂, d₁ are radii and thickness of a first cylindrical lens; and R₃, R₄, d₄ are radii and thickness of a second cylindrical lens; d₂ are d₃ are distances between the first and second cylindrical lens.

3. The work platform of claim 1, the work platform is configured to make the diffusion image appear on the focal plane of the ALCL, wherein the diffusion image is a “beam waist” shaped image;
wherein the concentration spatial profile of diffusion solution can be deduced from the diffusion image.

4. The work platform of claim 3, wherein the images are the diffusion images, the width of diffusion image (W) and the refractive index of diffusion solution (n) satisfy a function relationship;
wherein the function relationship between W and n can be determined either by solving imaging equations, or by measuring image-width and related refractive index of filled liquid.

5. A method for rapidly and precisely measuring concentration-dependent diffusion coefficients of binary solutions, comprising:
acquiring a liquid diffusion image at suitable time t₀ by means of an asymmetrical liquid-core cylindrical lens (ALCL);
binarizing the diffusion image;
extracting image width as a feature parameter, and changing the feature parameter into related refractive index of diffusion solution;
changing the refractive index into related concentration of diffusion solution;
acquiring experimental concentration profile along the diffusion direction C^{e}(zⱼ, t₀);
measuring the diffusion coefficient D₀ in the condition of infinite dilute solution based on the concentration profile C^{e}(zₚ t₀) in the range of low concentration area, which is the boundary condition for solving numerically Fick diffusion equation.

6. The method defined in claim 5, wherein the Fick diffusion equation is written as
$$\frac{\partial C ( z , t )}{\partial t} = \frac{\partial D ( C )}{\partial z} \frac{\partial C ( z , t )}{\partial z} + D ( C ) \frac{{\partial }^{2} C ( z , t )}{\partial {z}^{2}} ; \qquad ( C \text{-} 1 )$$
wherein C(z, t) is the concentration profile along the one-dimension diffusion direction z-axis at time t;
wherein D(C) is concentration-dependent diffusion coefficient, D(C) and is expressed in the form of polynomial
D(C)=D₀(1+aα₁C+α₂C²+α₃C³+ . . . ); (C-2)
wherein α₁, α₂, α₃, . . . are the under-determined coefficients.

7. The method of claim 6, wherein z=0 is the interface between two diffusion solutions, and initial concentrations in two sides of the interface be C₁ and C₂, the boundary conditions of Equation (C-1) satisfy with
$$\{ \begin{matrix}C ( z > 0 , t = 0 ) = {C}_{1} \\ C ( z \leq 0 , t = 0 ) = {C}_{2}\end{matrix} , \{ \begin{matrix}C ( z = H , t > 0 ) = {C}_{1} \\ C ( z = - H , t > 0 ) = {C}_{2}\end{matrix} . \qquad ( C \text{-} 3 )$$
wherein H is the solution height filled in the ALCL.

8. The method defined in claim 6: wherein a group of initial parameters [(α₁)₁, (α₂)₁, (α₃)₁] in Equation (C-2) are set by measurement tests to determine D(C);
wherein the algorithm of finite difference method (FDM), the implicit FDM and the chasing method in computational mathematics are used to solve numerically the Equation (C-1) under the initial and boundary conditions of Equation (C-3); and
writing the calculated concentration spatial and temporal profile at any diffusion time as Cⁿ(zⱼ, tᵢ), (j=0, 1, . . . M+1; i=0, 1, 2, . . . ).

9. The method defined in claim 8, wherein the calculated Cⁿ(zⱼ, tᵢ) at a special moment tᵢ=t₀ min is used to compare with the experimental profile C^{e}(zⱼ, t₀), (j=0, 1, 2, . . . , M+1), and standard deviation σₖ defined in Equation (C-4) is calculated as
$${σ}_{k} = \frac{\sqrt{{\sum }_{0}^{M + 1} {( {C}^{n} ( {z}_{j} , {t}_{0} ) - {C}^{e} ( {z}_{j} , {t}_{0} ) )}^{2}}}{\sqrt{M + 1}} , \\ ( j = 0 , 1 , … , M + 1 ; k = 1 , 2 , … , N ) . \qquad ( C \text{-} 4 )$$

10. The method defined in claim 9, wherein the comparing method is used to calculate a series σₖs(k=2, 3, . . . , N) by varying under-determined parameters [(α₁)ₖ, (α₂)ₖ, (α₃)ₖ];
wherein the parameters corresponding the minimum value of σₖs are the best-fit parameters, which are selected to determine
D(C)=D₀[1+(α₁)_{best}×C+(α₂)_{best}×C²±(α₃)_{best}×C³+ . . . ].

11. The method defined in claim 5, wherein the simulated diffusion images are compared with the experimental diffusion images to verify the correctness of calculated D(C).

12. The method of claim 8, comprising solving numerically the Equation (C-1) by using the FDM to get the refractive index spatial and temporal profile nⁿ(zⱼ, tᵢ) based on the calculated D(C);
applying a ray tracing method to simulate diffusion image at any diffusion time.
